(19) United States
(12) Patent Application Publication
(10) Pub. No.: US 2014/0290741 A1
(43) Pub. Date: Oct. 2, 2014

(54) PHOTOELECTRIC CONVERSION APPARATUS

(71) Applicants: Kazumasa Umesato, Omihachiman-shi (JP); Yukari Hashimoto, Yotsukaido-shi (JP); Shinya Ishikawa, Higashiomi-shi (JP)

(72) Inventors: Kazumasa Umesato, Omihachiman-shi (JP); Yukari Hashimoto, Yotsukaido-shi (JP); Shinya Ishikawa, Higashiomi-shi (JP)

(73) Assignee: KYOCERA Corporation, Kyoto-shi, Kyoto (JP)

(21) Appl. No.: 14/342,232

(22) PCT Filed: Jul. 27, 2012
(86) PCT No.: PCT/JP2012/069184

§ 371 Date: May 5, 2014

(30) Foreign Application Priority Data
Aug. 29, 2011 (JP) 2011-185536

(51) Int. Cl. H01L 31/0368; H01L 31/05; H01L 31/032

(52) U.S. Cl. CPC H01L 31/0368; H01L 31/0322; H01L 31/05
USPC 136/258

(57) ABSTRACT

A photoelectric conversion device is disclosed. The photoelectric conversion device includes: first and second electrode layers on a main surface of a substrate, separated by a space; a first semiconductor layer having a first conductivity type and containing crystal grains; a second semiconductor layer on the first semiconductor layer, having a second conductivity type different from the first conductivity type; and one or more first connection conductors on the second electrode layer, coupled to a side of the second semiconductor, and electrically connecting the second semiconductor layer to the second electrode layer. The first semiconductor layer includes: a first portion on the first electrode layer, including crystal grains having a first average size; a second portion disposed at the space on the substrate; and a third portion on the second electrode layer, including crystal grains having a second average size that is larger than the first average size.

### TECHNICAL FIELD

The present invention relates to photoelectric conversion devices including a plurality of photoelectric conversion cells connected together.

### BACKGROUND ART

Some photoelectric conversion devices for applications such as solar energy generation include a photoelectric conversion layer made of a chalcopyrite-type group I-III-VI compound semiconductor such as CIGS, which has a high optical absorption coefficient. Such photoelectric conversion devices are disclosed in, for example, Japanese Unexamined Patent Application Publication Nos. 2000-299486 and 2002-373995. CIGS, which has a high optical absorption coefficient, is suitable for forming a thinner and larger photoelectric conversion layer at a lower cost, and research and development has been directed to the use of CIGS for next-generation solar cells.

A chalcopyrite-type photoelectric conversion device includes a plurality of photoelectric conversion cells arranged side by side in a plane, each including, in sequence, a substrate such as a glass substrate, a lower electrode layer such as a metal electrode, a photoelectric conversion layer, and an upper electrode layer such as a transparent electrode or metal electrode. The upper electrode layer of one photoelectric conversion cell is connected to the lower electrode layer of another photoelectric conversion cell adjacent thereto with a connection conductor such that they are electrically connected in series.

Some photoelectric conversion devices including photoelectric conversion layers made of other materials such as silicon (Si)-based materials have similar structures.

The connection conductor is fabricated by removing a portion of the photoelectric conversion layer on the lower electrode layer by mechanical scribing and then providing a conductor therein. As the connection between the connection conductor and the lower electrode layer has a lower electrical resistance, less current loss occurs, and accordingly, the photoelectric conversion device has a higher photoelectric conversion efficiency.

However, with mechanical scribing, described above, the photoelectric conversion layer may be incompletely removed from the lower electrode layer and remain on the lower electrode layer. In this case, the remaining portion results in high contact resistance, which makes it difficult to improve the photoelectric conversion efficiency.

### SUMMARY OF INVENTION

In light of the foregoing problem, an object of the present invention is to provide a photoelectric conversion device with improved photoelectric conversion efficiency.

A photoelectric conversion device according to an embodiment of the present invention includes lower electrode layers, a first semiconductor layer, a second semiconductor layer, and a connection conductor. The lower electrode layers include a first lower electrode layer and a second lower electrode layer. The first lower electrode layer and the second lower electrode layer are arranged in a plane on a substrate and are separated from each other in one direction. The first semiconductor layer has a first conductivity type, is polycrystalline, and extends across the first lower electrode layer, the substrate, and the second lower electrode layer. The second semiconductor layer has a second conductivity type different from the first conductivity type and is disposed on the first semiconductor layer. The connection conductor extends along a surface (side surface) of the first semiconductor layer or through the first semiconductor layer and electrically connects the second semiconductor layer to the second lower electrode layer. Crystals in the first semiconductor layer near a connection between the connection conductor and the second lower electrode layer have a larger average grain size than crystals in the first semiconductor layer near the first lower electrode layer.

The above embodiment provides a photoelectric conversion device with improved conversion efficiency.

### BRIEF DESCRIPTION OF DRAWINGS

FIG. 1 is a perspective view showing an example of a photoelectric conversion device according to an embodiment of the present invention.

FIG. 2 is a sectional view of the photoelectric conversion device in FIG. 1.

FIG. 3 is a perspective view showing a modification of the photoelectric conversion device.

FIG. 4 is a sectional view of the photoelectric conversion device in FIG. 3.

FIG. 5 is a sectional view showing a photoelectric conversion device during manufacture.

FIG. 6 is a sectional view showing the photoelectric conversion device during manufacture.

FIG. 7 is a sectional view showing the photoelectric conversion device during manufacture.

FIG. 8 is a sectional view showing the photoelectric conversion device during manufacture.

FIG. 9 is a sectional view showing the photoelectric conversion device during manufacture.

FIG. 10 is a sectional view showing the photoelectric conversion device during manufacture.

FIG. 11 is a sectional view showing the photoelectric conversion device during manufacture.

### DESCRIPTION OF EMBODIMENTS

A photoelectric conversion device according to an embodiment of the present invention will now be described in detail with reference to the drawings.

### Structure of Photoelectric Conversion Device

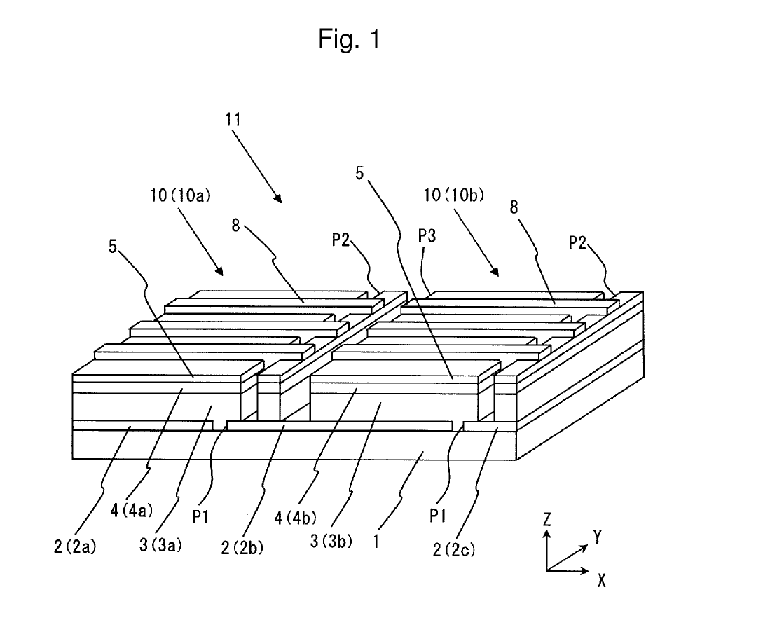

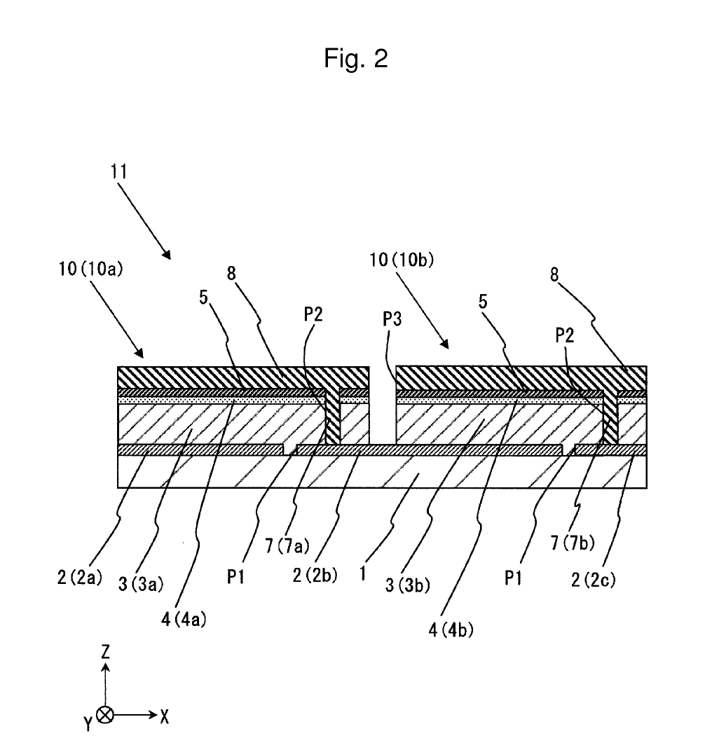

FIG. 1 is a perspective view showing an example of a photoelectric conversion device according to an embodiment of the present invention. FIG. 2 is an X-Z sectional view of the photoelectric conversion device 11 in FIG. 1. In FIGS. 1 and 2, a right-hand XYZ coordinate system is shown in which the X-axis direction is the direction in which photoelectric conversion cells 10 are arranged (the left-to-right direction as viewed in FIG. 1).

The photoelectric conversion device 11 includes a plurality of photoelectric conversion cells 10 arranged on a substrate 1 and electrically connected to each other. Although only two photoelectric conversion cells 10a and 10b are shown in FIG. 1 for illustration purposes, the photoelectric conversion device 11 may in practice include a large number of photoelectric conversion cells 10 arranged in the X-axis direction in the drawings or in a plane (two-dimensionally) in the X-axis and Y-axis directions in the drawings.

In FIGS. 1 and 2, a plurality of lower electrode layers 2 are arranged in a plane on the substrate 1. In FIGS. 1 and 2, the plurality of lower electrode layers 2 include lower electrode layers 2a to 2c arranged in one direction (X-axis direction) at intervals (the gaps between the adjacent lower electrode layers 2 are hereinafter referred to as first grooves P1). A first semiconductor layer 3a extends across the lower electrode layer 2a (the first lower electrode layer of the photoelectric conversion cell 10a), the substrate 1, and the lower electrode layer 2b (the second lower electrode layer of the photoelectric conversion cell 10a). A second semiconductor layer 4a of a conductivity type different from that of the first semiconductor layer 3a is disposed on the first semiconductor layer 3a. Connection conductors 7a are disposed on the lower electrode layer 2b and extend along a surface (side surface) of the first semiconductor layer 3a or extend through (divide) the first semiconductor layer 3a. The connection conductors 7a electrically connect the second semiconductor layer 4a to the lower electrode layer 2b. The lower electrode layer 2a, the lower electrode layer 2b, the first semiconductor layer 3a, the second semiconductor layer 4a, and the connection conductors 7a constitute the photoelectric conversion cell 10a.

Similarly, another photoelectric conversion cell 10b is disposed adjacent to the photoelectric conversion cell 10a. Specifically, a first semiconductor layer 3b and a second semiconductor layer 4b extend across the lower electrode layer 2b (the first lower electrode layer of the photoelectric conversion cell 10b) and the lower electrode layer 2c (the second lower electrode layer of the photoelectric conversion cell 10b). Connection conductors 7b are disposed on the lower electrode layer 2c and electrically connect the second semiconductor layer 4b to the lower electrode layer 2c. The lower electrode layer 2b, the lower electrode layer 2c, the first semiconductor layer 3b, the second semiconductor layer 4b, and the connection conductors 7b constitute the photoelectric conversion cell 10b.

The photoelectric conversion cells 10a and 10b share the lower electrode 2b, thus constituting a high-output photoelectric conversion device 11 in which the photoelectric conversion cells 10a and 10b are connected in series.

Although the photoelectric conversion device 11 according to this embodiment is configured to receive light through the second semiconductor layers 4, it may be configured in other ways, for example, to receive light through the substrate 1.

The substrate 1 supports the photoelectric conversion cells 10. Examples of materials used for the substrate 1 include glasses, ceramics, resins, and metals. For example, the substrate 1 may be a soda-lime glass substrate having a thickness of about 1 to 3 mm.

The lower electrode layers 2 (lower electrode layers 2a, 2b, and 2c) on the substrate 1 are made of a conductor such as molybdenum, aluminum, titanium, or gold. The lower electrode layers 2 are deposited to a thickness of about 0.2 to 1 μm by a known thin-film deposition process such as sputtering or evaporation.

The first semiconductor layers 3 (first semiconductor layers 3a and 3b), serving as photoelectric conversion layers, are polycrystalline semiconductor layers of a first conductivity type. The first semiconductor layers 3 have a thickness of, for example, about 1 to 3 μm. Examples of materials for the first semiconductor layers 3 include silicon, group II-VI compounds, group I-III-VI compounds, and group I-II-IV-VI compounds.

Group II-VI compounds are compound semiconductors of group II-B elements (also called group 12 elements) and group VI-B elements (also called group 16 elements). Examples of group II-VI compounds include CdTe.

Group I-III-VI compounds are compound semiconductors of group I-B elements (also called group 11 elements), III-B elements (also called group 13 elements), and group VI-B elements. Examples of group I-III-VI compounds include CuInSe₂ (copper indium diselenide, also called CIS), Cu(In,Ga)Se₂ (copper indium gallium diselenide, also called CICS), and Cu(In,Ga)(Se,S)₂ (copper indium gallium diselenide/sulfide, also called CIGSS). Alternatively, the first semiconductor layers 3 may be made of a multinary compound semiconductor thin film such as a copper indium gallium diselenide film having a thin layer of copper indium gallium diselenide/sulfide as a surface layer.

Group I-II-IV-VI compounds are compounds of group I-B elements, group II-B elements, group IV-B elements (also called group 14 elements), and group VI-B elements. Examples of group I-II-IV-VI compounds include Cu₂ZnSnS₄ (also called CZTS), Cu₂ZnSn(S,Se)₄ (also called CZTSSe), and Cu₂ZnSnSe₄ (also called CZTSe).

The first semiconductor layers 3 can be formed by a vacuum process such as sputtering or evaporation or by a process called coating or printing. A process called coating or printing is a process in which a complex solution of the constituent elements of the first semiconductor layers 3 is applied to the lower electrode layers 2, followed by drying and heat treatment.

In the photoelectric conversion cell 10a, the crystals in the first semiconductor layer 3a near the connections between the connection conductors 7a and the lower electrode layer 2b (the second lower electrode layer of the photoelectric conversion cell 10a) have a larger average grain size than the crystals in the first semiconductor layer 3a near the lower electrode layer 2a (the first lower electrode layer of the photoelectric conversion cell 10a). Thus, when a portion of the first semiconductor layer 3a on the lower electrode layer 2b is removed to expose the lower electrode layer 2b before forming the connection conductors 7a, less first semiconductor layer 3a remains on the surface of the lower electrode layer 2b. This allows the connections between the connection conductors 7a and the lower electrode layer 2b to have a lower electrical resistance, thus improving the photoelectric conversion efficiency of the photoelectric conversion device 11.

Specifically, because the crystals in the first semiconductor layer 3a near the connections between the connection conductors 7a and the lower electrode layer 2b have a relatively large average grain size, this portion of the first semiconductor layer 3a has low adhesion to the lower electrode layer 2b and is therefore easily removed. In contrast, because the crystals in the first semiconductor layer 3a near the lower electrode layer 2a have a relatively small average grain size, this portion of the first semiconductor layer 3a has high adhesion to the lower electrode layer 2a and therefore has a good electrical connection to the lower electrode layer 2a.

Similarly, in the photoelectric conversion cell 10b, the crystals in the first semiconductor layer 3b near the connections between the connection conductors 7b and the lower electrode layer 2c (the second lower electrode layer of the photoelectric conversion cell 10b) have a larger average grain size than the crystals in the first semiconductor layer 3b near the lower electrode layer 2b (the first lower electrode layer of the photoelectric conversion cell 10b). Thus, when a portion of the first semiconductor layer 3b on the lower electrode layer 2c is removed to expose the lower electrode layer 2c before forming the connection conductors 7b, less first semiconductor layer 3b remains on the surface of the lower electrode layer 2c. This allows the connections between the connection conductors 7b and the lower electrode layer 2c to have a lower electrical resistance, thus improving the photoelectric conversion efficiency of the photoelectric conversion device 11.

In the photoelectric conversion cell 10a, the average grain size of the crystals in the first semiconductor layer 3a near the connections between the connection conductors 7a and the lower electrode layer 2b may be 2 to 100 times as large as that of the crystals in the first semiconductor layer 3a near the lower electrode layer 2a. If the average grain size falls within the above range, the photoelectric conversion device 11 has a higher photoelectric conversion efficiency. To form a more durable photoelectric conversion cell 10a, the average grain size of the crystals in the first semiconductor layer 3a near the connections between the connection conductors 7a and the lower electrode layer 2b may be 2 to 5 times as large as that of the crystals in the first semiconductor layer 3a near the lower electrode layer 2a. Similarly, in the photoelectric conversion cell 10b, the average grain size of the crystals in the first semiconductor layer 3b near the connections between the connection conductors 7b and the lower electrode layer 2c may be 2 to 100 times as large as that of the crystals in the first semiconductor layer 3b near the lower electrode layer 2b. If the average grain size falls within the above range, the photoelectric conversion device 11 has a higher photoelectric conversion efficiency. To form a more durable photoelectric conversion cell 10b, the average grain size of the crystals in the first semiconductor layer 3b near the connections between the connection conductors 7b and the lower electrode layer 2c may be 2 to 5 times as large as that of the crystals in the first semiconductor layer 3b near the lower electrode layer 2b.

The crystals in the first semiconductor layer 3a near the lower electrode layer 2a (the first lower electrode layer of the photoelectric conversion cell 10a) and the crystals in the first semiconductor layer 3b near the lower electrode layer 2b (the first lower electrode layer of the photoelectric conversion cell 10b) may have average grain sizes of 20 to 1,000 nm. This enhances the adhesion between the lower electrode layers 2 and the first semiconductor layers 3 and also facilitates charge transfer therebetween.

The average grain size of the crystals in the first semiconductor layer 3a near the connections between the connection conductors 7a and the lower electrode layer 2b (the second lower electrode layer of the photoelectric conversion cell 10a) is the average grain size of the crystal grains in the first semiconductor layer 3a in contact with the lower electrode layer 2b between the connection conductors 7a and the groove P1 (the groove P1 between the lower electrode layer 2a and the lower electrode layer 2b) in the cross-section of the photoelectric conversion device 11 as shown in FIG. 2.

The average grain size of the crystals in the first semiconductor layer 3a near the lower electrode layer 2a (the first lower electrode layer of the photoelectric conversion cell 10a) is the average grain size of the crystal grains in the first semiconductor layer 3a in contact with the lower electrode layer 2a in the cross-section of the photoelectric conversion device 11 as shown in FIG. 2.

Similarly, the average grain size of the crystals in the first semiconductor layer 3b near the connections between the connection conductors 7b and the lower electrode layer 2c (the second lower electrode layer of the photoelectric conversion cell 10b) is the average grain size of the crystal grains in the first semiconductor layer 3b in contact with the lower electrode layer 2c between the connection conductors 7b and the groove P1 (the groove P1 between the lower electrode layer 2b and the lower electrode layer 2c). The average grain size of the crystals in the first semiconductor layer 3b near the lower electrode layer 2b (the first lower electrode layer of the photoelectric conversion cell 10b) is the average grain size of the crystal grains in the first semiconductor layer 3b in contact with the lower electrode layer 2b.

The average grain size of the crystals in the first semiconductor layers 3 can be determined, for example, as follows. An image of a cross-section (cross-sectional image) of the photoelectric conversion device 11 as shown in FIG. 2 is captured under a scanning electron microscope (SEM). With a transparent film placed on the cross-sectional image, a pen is moved along the boundaries between a plurality of crystal grains in the first semiconductor layers 3 in contact with the lower electrode layers 2. At the same time, the pen is moved along a straight line (also called a scale bar) displayed near a corner of the cross-sectional image and indicating a predetermined distance (for example, 1 μm). The transparent film on which the grain boundaries and the scale bar are written with the pen is scanned with a scanner to acquire image data. The areas of the crystal grains are then calculated from the image data using predetermined image processing software, and the sphere equivalent diameters of the crystal grains are calculated from the areas thereof. Ten or more evenly distributed crystal grains are selected, and the average grain diameter thereof is calculated as the average grain size.

The second semiconductor layers 4 (second semiconductor layers 4a and 4b) are semiconductor layers of a second conductivity type different from the first conductivity type of the first semiconductor layers 3. The first semiconductor layers 3 and the second semiconductor layers 4 are electrically connected together to form photoelectric conversion layers from which charge can be smoothly extracted. For example, if the first semiconductor layers 3 are p-type, the second semiconductor layers 4 are n-type. Alternatively, the first semiconductor layers 3 may be n-type, and the second semiconductor layers 4 may be p-type. High-resistance buffer layers may be disposed between the first semiconductor layers 3 and the second semiconductor layers 4.

The second semiconductor layers 4 may be layers formed on the first semiconductor layers 3 using a material different from that of the first semiconductor layers 3 or may be surface portions of the first semiconductor layers 3 modified by doping with other elements.

Examples of materials for the second semiconductor layers 4 include CdS, ZnS, ZnO, In₂S₃, In₂Se₃, In(OH,S), (Zn,In)(Se,OH), and (Zn,Mg)O. In this case, the second semiconductor layers 4 are deposited to a thickness of 10 to 200 nm, for example, by chemical bath deposition (CBD). In(OH,S) is a compound based on indium, hydroxy, and sulfur. (Zn,In)(Se,OH) is a compound based on zinc, indium, selenium, and hydroxy. (Zn,Mg)O is a compound based on zinc, magnesium, and oxygen.

As shown in FIGS. 1 and 2, upper electrode layers 5 may be disposed on the second semiconductor layers 4. The upper electrode layers 5 have a lower resistivity than the second semiconductor layers 4 and thus allow charge to be smoothly extracted from the first semiconductor layers 3 and the second semiconductor layers 4. To further improve the photoelectric conversion efficiency, the upper electrode layers 5 may have a resistivity of less than 1 Ω·cm and a sheet resistance of 50 Ω/sq or less.

For example, the upper electrode layers 5 are transparent conductive films made of a material such as ITO or ZnO and having a thickness of 0.05 to 3 μm. To increase the transparency and conductivity, the upper electrode layers 5 may be made of a semiconductor of the same conductivity type as that of the second semiconductor layers 4. The upper electrode layers 5 can be formed, for example, by sputtering, evaporation, or chemical vapor deposition (CVD).

As shown in FIGS. 1 and 2, collector electrodes 8 may be formed on the upper electrode layers 5. The collector electrodes 8 allow charge to be more smoothly extracted from the first semiconductor layers 3 and the second semiconductor layers 4. For example, as shown in FIG. 1, the collector electrodes 8 are formed in stripes extending from an end of each photoelectric conversion cell 10 to the connection conductors 7. This allows current to be collected from the first semiconductor layers 3 and the second semiconductor layers 4 through the upper electrode layers 5 to the collector electrodes 8 so that it flows smoothly through the connection conductors 7 into the adjacent photoelectric conversion cells 10.

To increase the transparency to light passing to the first semiconductor layers 3 while ensuring good conductivity, the collector electrodes 8 may have a width of 50 to 400 μm. The collector electrodes 8 may include a plurality of branch portions.

The collector electrodes 8 are formed, for example, by printing a pattern of a metal paste containing a metal powder, such as silver powder, dispersed in a material such as a resin binder and then curing the pattern.

In FIGS. 1 and 2, the connection conductors 7 (connection conductors 7a and 7b) are conductors in second grooves P2 that extend through (divide) the first semiconductor layers 3, the second semiconductor layers 4, and the second electrode layers 5 in the Z-axis direction. The connection conductors 7 can be formed, for example, from a metal or conductive paste. Although the connection conductors 7 extend from the collector electrodes 8 in FIGS. 1 and 2, they may be configured in other ways. For example, the connection conductors 7 may extend from the upper electrode layers 5.

To enhance the adhesion between the connection conductors 7 and the lower electrode layers 2 and the adhesion between the connection conductors 7 and the first semiconductor layers 3, the connection conductors 7 may contain glass. Such connection conductors 7 can effectively reduce peeling of the first semiconductor layers 3 near the connection conductors 7, thus providing a photoelectric conversion device 11 that can maintain its high photoelectric conversion efficiency over an extended period of time. That is, although the relatively large average grain size of the crystals near the connections between the connection conductors 7 and the lower electrode layers 2 tends to decrease the adhesion strength between the first semiconductor layers 3 and the lower electrode layers 2 near the connections, the connection conductors 7, containing glass, can reinforce the adhesion therebetween.

### Process of Manufacturing Photoelectric Conversion Device

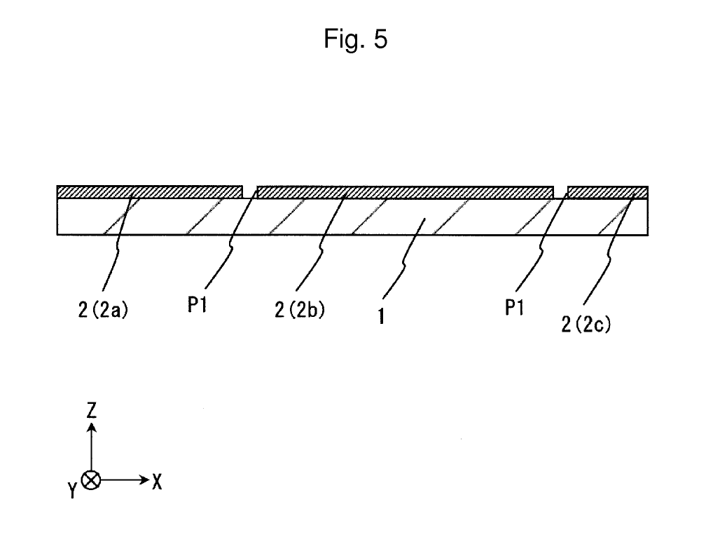

Next, a process of manufacturing the thus-configured photoelectric conversion device 11 will be described. FIGS. 5 to 11 are sectional views showing the photoelectric conversion device 10 during manufacture. The sectional views in FIGS. 5 to 11 show the portion corresponding to the cross-section in FIG. 2 during manufacture.

Referring first to FIG. 5, a lower electrode layer 2 of a material such as molybdenum is formed substantially over the entire surface of a cleaned substrate 1 by a process such as sputtering. The first grooves P1 are then formed in the lower electrode layer 2. The first grooves P1 are formed, for example, by laser scribing, in which grooves are formed by scanning a laser beam emitted from a laser such as a YAG laser along the positions where the first grooves P1 are to be formed. FIG. 5 shows the state after the first grooves P1 are formed.

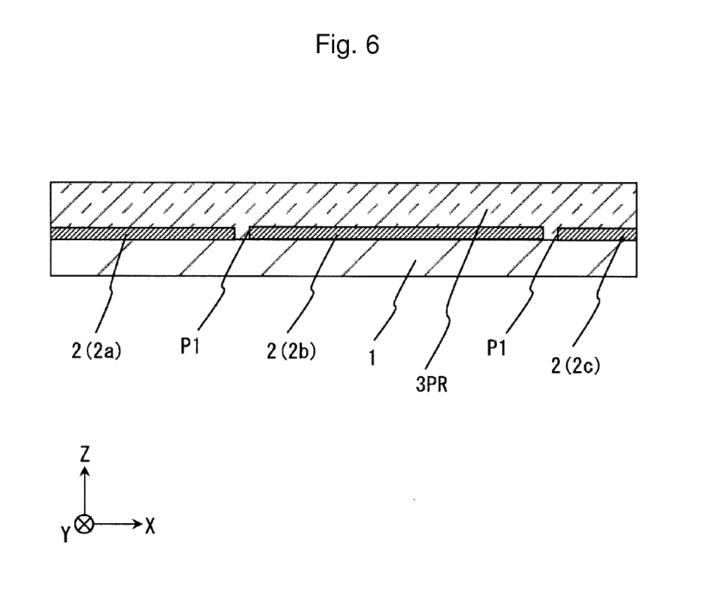

After the first grooves P1 are formed, a precursor layer 3PR that is to form the first semiconductor layers 3 is formed on the lower electrode layers 2 by a process such as sputtering or coating. The precursor layer 3PR may be a layer containing the raw materials for the compound that forms the first semiconductor layers 3 or may be a layer containing fine particles of the compound that forms the first semiconductor layers 3. FIG. 6 shows the state after the precursor layer 3PR is formed.

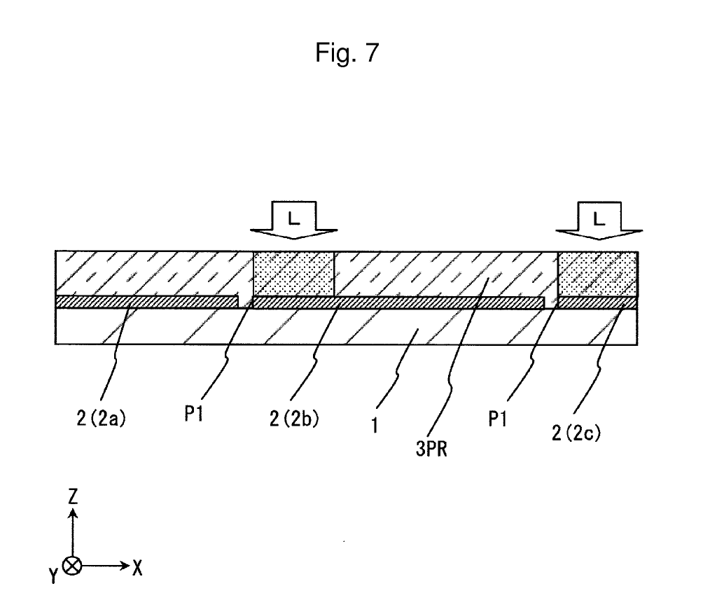

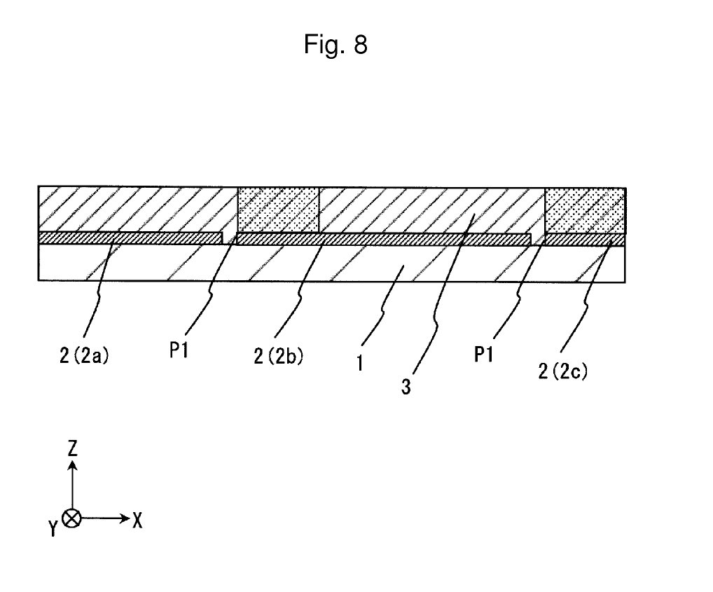

Next, the portions of the precursor layer 3PR where the connection conductors 7 are to be formed are sprayed with a solution L containing an alkali metal element such as sodium, for example, using a spray to increase the concentration of the alkali metal element before the entire precursor layer 3PR is heated for crystallization. During the heating, large crystal grains tend to form in the portions sprayed with the solution L because the alkali metal element promotes crystallization. FIG. 7 shows the state in which the portions of the precursor layer 3PR where the connection conductors 7 are to be formed are being sprayed with the solution L. The solution L containing the alkali metal element may be, for example, a solution of an inorganic compound such as sodium chloride or sodium nitrate or an organic complex such as a sodium acetate complex in a solvent such as water or an alcohol. FIG. 8 shows the state after the precursor layer 3PR is crystallized to form a first semiconductor layer 3.

The grain sizes of the crystals in the portions of the first semiconductor layer 3 where the connection conductors 7 are to be formed may be increased by methods other than spraying the solution L. For example, the entire precursor layer 3PR may be heated for crystallization while locally heating the portions of the precursor layer 3PR where the connection conductors 7 are to be formed, for example, using a lamp or laser. Thus, the locally heated portions are heated to a higher temperature than other portions, which tends to promote crystallization and thus form large crystal grains.

Alternatively, the precursor layer 3PR may be crystallized while allowing a large amount of alkali metal element to diffuse from the substrate 1 through holes or thin areas formed in the portions of the lower electrode layers 2 corresponding to the portions of the precursor layer 3PR where the connection conductors 7 are to be formed.

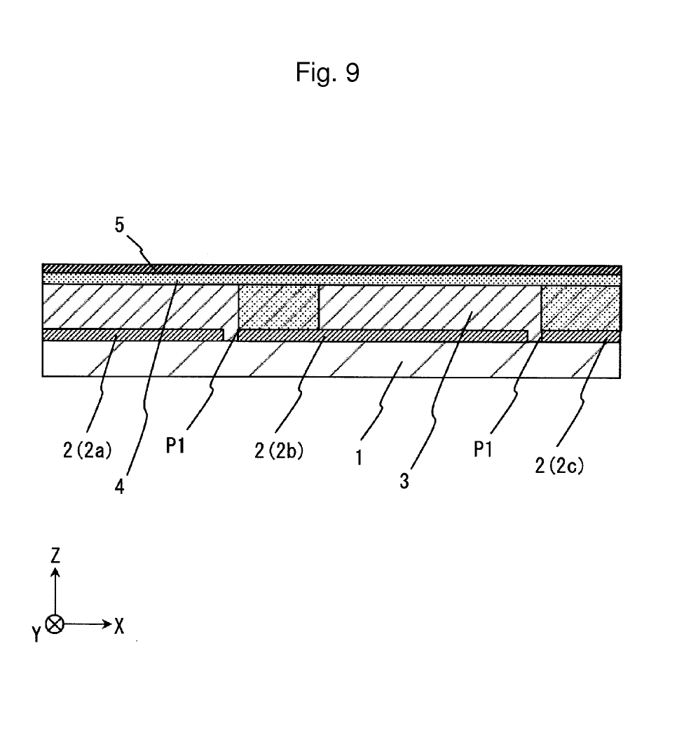

After the first semiconductor layer 3 is formed, a second semiconductor layer 4 and an upper electrode layer 5 are sequentially formed on the first semiconductor layer 3 by a process such as CBD or sputtering. FIG. 9 shows the state after the second semiconductor layer 4 and the upper electrode layer 5 are formed.

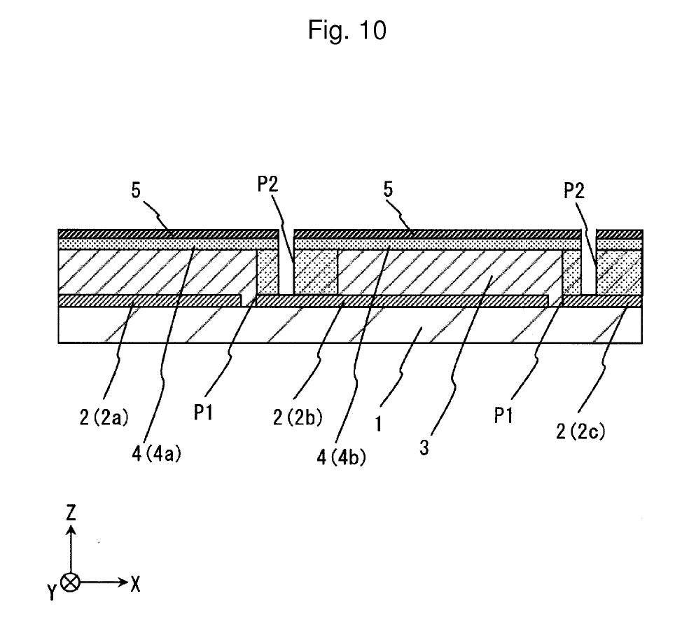

After the second semiconductor layer 4 and the upper electrode layer 5 are formed, the second grooves P2 are formed by mechanical scribing such that they extend through (divide) the first semiconductor layer 3, the second semiconductor layer 4, and the upper electrode layer 5. Mechanical scribing is a process in which the first semiconductor layer 3 is removed from the lower electrode layer 2 by scribing, for example, using a scribing needle or drill with a scribing width of about 40 to 50 μm. Because the second grooves P2 are formed in the portions of the first semiconductor layer 3 where the connection conductors 7 are to be formed, i.e., the portions composed of large crystal grains, mechanical scribing can be smoothly performed, and therefore, the first semiconductor layer 3 can be smoothly removed from the lower electrode layers 2. FIG. 10 shows the state after the second grooves P2 are formed.

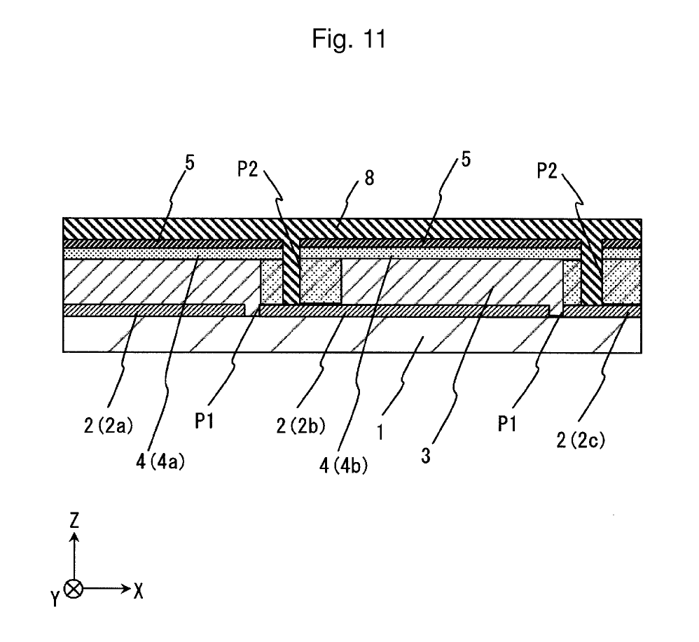

After the second grooves P2 are formed, the collector electrodes 8 and the connection conductors 7 are formed, for example, by printing a pattern of a conductive paste containing a metal powder, such as silver powder, dispersed in a material such as a resin binder on the upper electrode layers 5 and in the second grooves P2 and then curing the pattern by heating. FIG. 11 shows the state after the collector electrodes 8 and the connection conductors 7 are formed.

Finally, the layers from the first semiconductor layer 3 to the collector electrodes 8 are removed at positions away from the second grooves P2 by mechanical scribing to divide the layers into a plurality of photoelectric conversion cells. In this manner, the photoelectric conversion device 11 shown in FIGS. 1 and 2 can be manufactured.

### Modification of Photoelectric Conversion Device

The present invention is not limited to the embodiment described above; various modifications and improvements are permitted without departing from the spirit of the present invention.

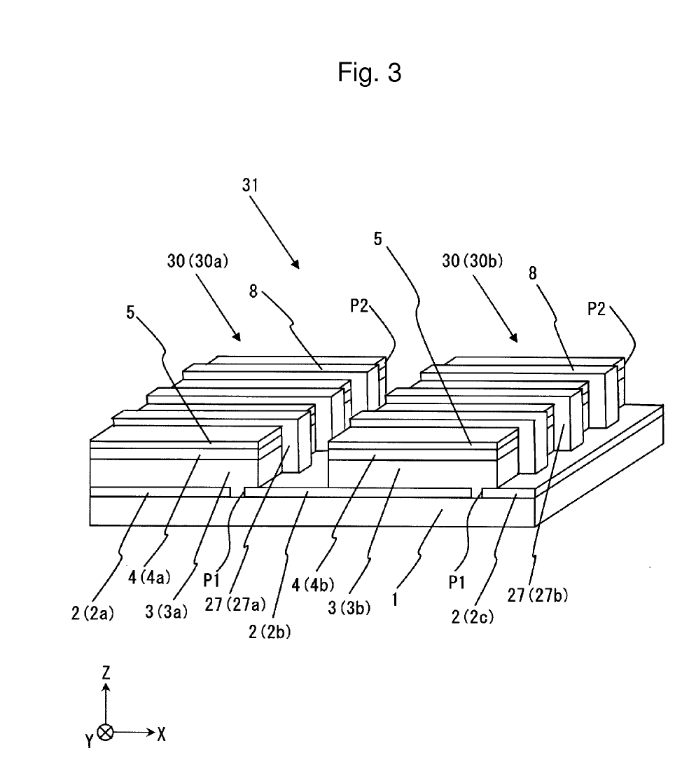

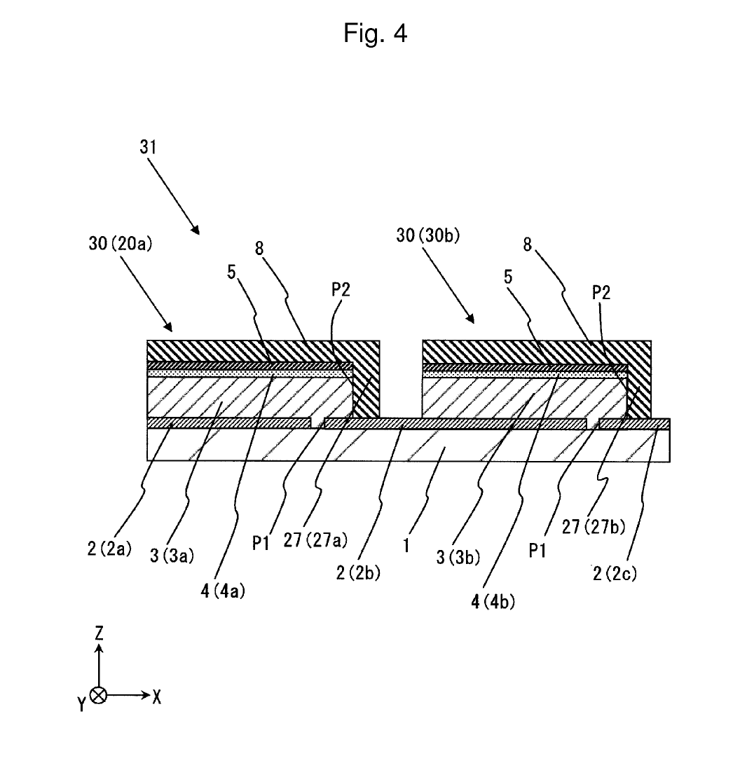

For example, although the above embodiment illustrates the connection conductors 7 that extend through (divide) the first semiconductor layers 3, they may be configured in other ways. For example, as shown in FIGS. 3 and 4, connection conductors 27 extending along surfaces (side surfaces) of the first semiconductor layers 3 may be formed. In FIGS. 3 and 4, the same components as those in FIGS. 1 and 2 are labeled with the same reference signs.

A photoelectric conversion device 31 shown in FIGS. 3 and 4 includes a plurality of photoelectric conversion cells 30 (photoelectric conversion cells 30a and 30b). The photoelectric conversion cell 30a includes connection conductors 27a extending along side surfaces of a first semiconductor layer 3a, a second semiconductor layer 4a, and an upper electrode layer 5. Similarly, the photoelectric conversion cell 30b includes connection conductors 27b extending along side surfaces of a first semiconductor layer 3b, a second semiconductor layer 4b, and an upper electrode layer 5.

The photoelectric conversion device 31 can be fabricated, for example, by forming relatively wide second grooves P2 in FIG. 10 and then forming the connection conductors 27 such that they are not in contact with the second semiconductor layers 4 and upper electrode layers 5 of the adjacent photoelectric conversion cells. This eliminates the need for the final step of dividing the layers into photoelectric conversion cells, thus simplifying the process.

### REFERENCE SIGNS LIST

1: substrate

2, 2a, 2b: lower electrode layer

3, 3a, 3b: first semiconductor layer

4, 4a, 4b: second semiconductor layer

7, 7a, 7b, 27, 27a, 27b: connection conductor

10, 10a, 10b, 30, 30a, 30b: photoelectric conversion cell

11, 31: photoelectric conversion device

1. A photoelectric conversion device comprising:
a substrate;
first and second electrode layers on a main surface of the substrate separated by a first space;
a first semiconductor layer, having a first conductivity type, containing crystal grains, and comprising:
a first portion on the first electrode layer, comprising crystal grains having a first average grain size;
a second portion at the first space on the substrate; and
a third portion on the second electrode layer, comprising crystal grains having a second average grain size that is larger than the first average grain size;
a second semiconductor layer having a second conductivity type different from the first conductivity type, and disposed on the first semiconductor layer; and
one or more first connection conductors on the second electrode layer, coupled to a side of the second semiconductor layer, and electrically connecting the second semiconductor layer to the second electrode layer.

2. The photoelectric conversion device according to claim 1, wherein the second average grain size is 2 to 100 times as large as the first average grain size.

3. The photoelectric conversion device according to claim 1, wherein
the first semiconductor layer contains a metal chalcogenide and an alkali metal element, and
concentration of the alkali metal element in the third portion is larger than that in the first portion.

4. The photoelectric conversion device according to claim 3, wherein the metal chalcogenide is a group I-III-VI compound.

5. The photoelectric conversion device according to claim 1, wherein the connection conductor contains glass.

6. The photoelectric conversion device according to claim 1, further comprising:
a third electrode layer on the main surface, separated from the second electrode layers by a second space, wherein the first, second and third electrode layers disposed in line;
a third semiconductor layer having the first conductivity type, containing crystal grains, and comprising:
a fourth portion on the second electrode layer;
a fifth portion at the second space on the substrate; and
a sixth portion on the third electrode layer;
a fourth semiconductor layer on the third semiconductor layer, having the second conductivity type; and
one or more second connection conductors on the third electrode layer, coupled to a side of the third semiconductor layer, and electrically connecting the fourth semiconductor layer to the third electrode layer.
